(19) United States
(12) Patent Application Publication
(10) Pub. No.: US 2011/0188208 A1
(43) Pub. Date: Aug. 4, 2011

(54) HEAT DISSIPATING SYSTEM

(75) Inventor: JENG-DA WU, Tu-Cheng (TW)

(73) Assignee: HON HAI PRECISION INDUSTRY CO., LTD., Tu-Cheng (TW)

(21) Appl. No.: 12/830,483

(22) Filed: Jul. 6, 2010

(30) Foreign Application Priority Data
Feb. 1, 2010 (CN) 201020302010.8

(51) Int. Cl. H05K 7/20

(52) U.S. Cl. 361/719

(57) ABSTRACT

A heat dissipating system includes a circuit board, a chip module, a first clamping member, a second clamping member, and a plurality of stress adjusting members. The circuit board includes a top surface and a bottom surface opposite to the top surface. The chip module includes a base portion located on the top surface of the circuit board via solder balls and a chip disposed on the base portion. The first clamping member abuts the chip. The second clamping member abuts the bottom surface of the circuit board. The stress adjusting members extend through the second clamping member and engage with the first clamping member.

This application is related to copending application entitled, “CIRCUIT BOARD ASSEMBLY”, filed on Apr. 2, 2010, application Ser. No. 12/753,299, (Atty. Docket No. US30926).

### BACKGROUND

1. Technical Field

The present disclosure relates to a heat dissipating system for cooling a chip.

2. Description of Related Art

A semiconductor chip is usually mounted on a circuit board by soldering spots of the semiconductor chip to the circuit board using a leaded solder material. The alloy resists damage easily, because of lead's resistance to shock. Due to environmental and health concerns, though, nonleaded solder is now commonly used. However, with the non-leaded solder's low shock resistance, damage can easily occur, thereby affecting signal transmission between the semiconductor chip and the circuit board.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of a heat dissipating system in accordance with an embodiment.

FIG. 2 is an assembled view of FIG. 1.

FIG. 3 is a cut view of the heat dissipating system mounted in a chassis, along a direction III-III.

FIG. 4 is an enlarged view of portion IV in FIG. 3.

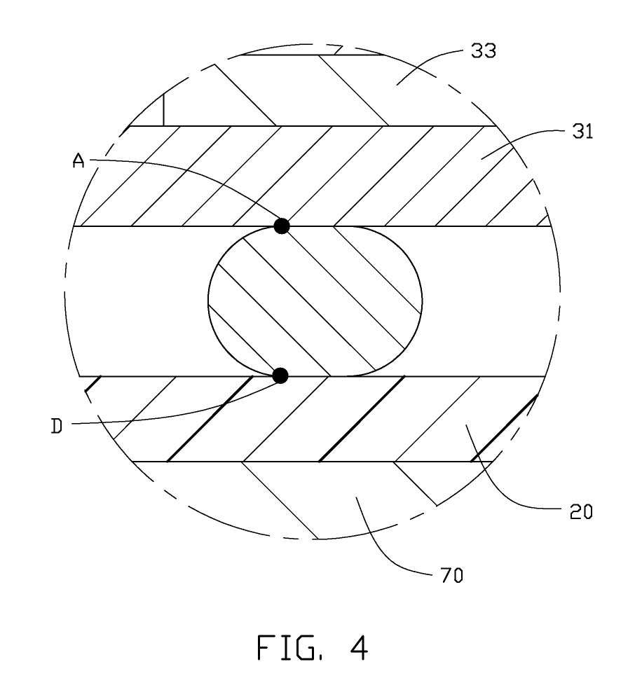

FIG. 5 is a diagram of an acceleration curve used for simulating impact applied to the heat dissipating system.

FIG. 6 shows a curve illustrating points A and D of solder material disposed on a conventional heat dissipating system.

FIG. 7 shows a curve illustrating points A and D of the heat dissipating system in FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

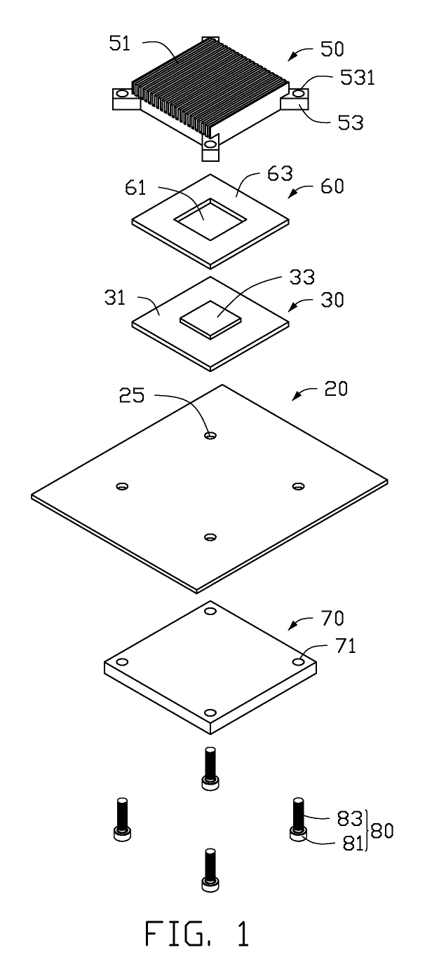

Referring to FIG. 1, a heat dissipating system in accordance one embodiment includes a first clamping member 50, a second clamping member 70, a circuit board 20, and a plurality of stress adjusting members 80.

The first clamping member 50 includes a main body 51. In one embodiment, the main body 51 includes a plurality of parallel fins. A plurality of blocks 53 is located on the main body 51. In one embodiment, the main body 51 is rectangle, the number of the blocks 53 is four, and the four blocks 53 are integrated with four corners of the main body 51. Each block 53 defines a fixing hole 531. The fixing holes 531 may be, for example, threaded holes. In one embodiment, the first clamping member 50 is a heat sink.

The second clamping member 70 defines a plurality of mounting holes 71, corresponding to the fixing holes 531 of first clamping member 50. In one embodiment, the shape of the second clamping member 70 is similar to the shape of the main body 51. In one embodiment, the mounting holes 71 are threaded holes.

The circuit board 20 defines a plurality of through holes 25. For example, the circuit board 20 may be a motherboard. A chip module 30 is configured to be secured to the circuit board 20 among the through holes 25. The chip module 30 includes a base portion 31 and a chip 33 secured to the base portion 31. A supporting member 60 is configured to be located on the base portion 31. The supporting member 60 defines an opening 61 for receiving the chip 33. In one embodiment, the height of the supporting member 60 is substantially equal to the height of the chip 33.

Each stress adjusting member 80 includes a head 81 and a neck 83 connected to the head 81. The neck 83 has a screw thread. In one embodiment, the stress adjusting members 80 are screws.

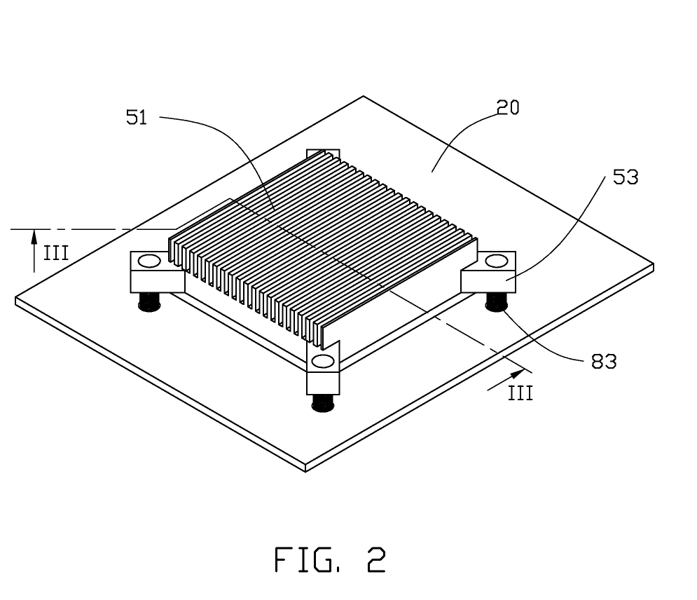

Referring to FIG. 2, in assembly, the chip module 30 is secured to a top surface of the circuit board 20 among the through holes 25. The supporting member 60 is located on the base portion 31, and the chip 33 is received in the opening 61. The second clamping member 70 is attached to a bottom surface of the circuit board 20, and the mounting holes 71 correspond to the through holes 25. The necks 83 of the stress adjusting members 80 are engaged into the mounting holes 71 and the through holes 25 and exposed out of the top surface of the circuit board 20. The first clamping member 50 is placed on the supporting member 60 and the chip 33, and the fixing holes 531 correspond to the stress adjusting members 80. Then the stress adjusting members 80 are screwed into the fixing holes 531, to secure the first clamping member 50 on the circuit board 20.

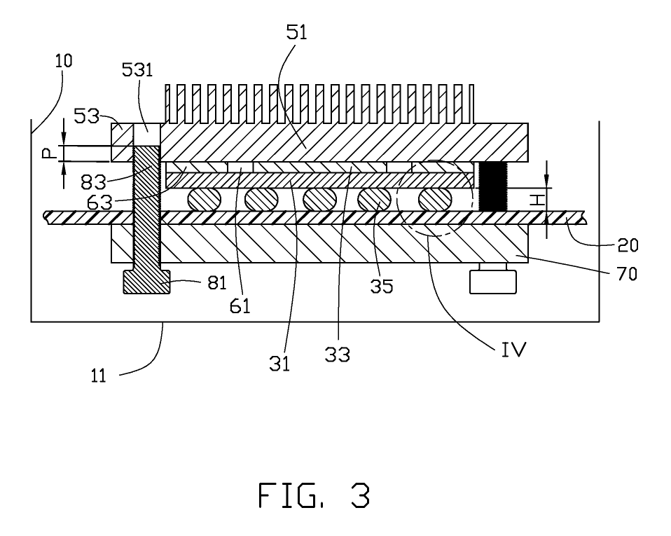

Referring to FIG. 3, the base portion 31 of the chip module 30 is secured to the circuit board 20 by jointing, so a plurality of solder balls 35 is located between the base portion 31 and the circuit board 20, to electrically connect the chip module 30 and the circuit board 20. The heat dissipating system is secured to a bottom wall 11 of a chassis 10. The circuit board 20 is substantially parallel to the bottom wall 11. There is a length P that each stress adjusting member 80 is inserted in the corresponding fixing hole 531, and there is a distance H between the bottom surface of the base portion 31 of the chip module 30 and the top surface of the circuit board 20 or a height H of the solder balls 35. A height of the second clamping member is less than a distance between the bottom surface of the circuit board 20 and the bottom wall 11.

When the chassis 10 suffers an impact, tensile stress on the solder balls 35 between the circuit board 20 and the chip module 30 is reduced. Since the circuit board 20 and the chip module 30 are clamped between the first clamping member 50 and the second clamping member 70, the solder balls 35 are already under compression. Thereby, the solder balls 35 are protected from being damaged.

The compressive stress applied to the solder balls 35 is determined by the stress adjusting members 80. The compressive stress applied to the solder balls 35 may be adjusted according to a ratio value of the length P to the height H, or a distance between the base portion 31 and the circuit board 20. As ratio value P/H increases, stress applied to the solder balls 35 increases correspondingly. The stress adjusting members 80 may be operated to adjust the compressive stress applied on the solder balls 35, to counteract the tensile stress applied on the solder balls 35 during an impact.

At rest, the relationship between the ratio value P/H and the compressive stress applied to the solder balls 35 by different embodiments using different materials can be expressed as:

| P/H (%) | SnAgCu (Mpa) | Sn/Pb (Mpa) |
|---|---|---|
| 0.1 | 4.3 | 3.4 |
| 0.3 | 12.9 | 10.2 |
| 0.5 | 21.5 | 17 |
| 0.75 | 32.25 | 25.5 |
| 1 | 43 | 34 |
| 1.25 | 53.75 | 42.5 |
| 1.5 | 64.5 | 51 |
| 1.75 | 75.25 | 59.5 |
| 2 | 86 | 68 |
| 2.25 | 96.75 | 76.5 |
| 2.5 | 107.5 | 85 |
| 2.75 | 118.25 | 93.5 |
| 3 | 129 | 102 |

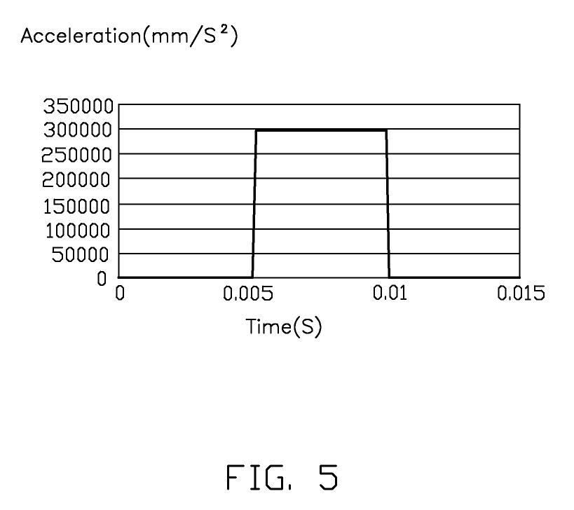

As shown in FIGS. 5 to 7, an application LS-DYNA, which is a well known simulation software, simulates first principal stress applied to the solder balls 35 when the circuit board 20 suffers an impact. Generally, when the heat dissipating system suffers an impact, the joints between the circuit board 20 and the solder balls 35 and between the base portion 31 and the solder balls 35 suffer greater stress. Accordingly, during the simulation, only the first principal stress, applied to a point A of one solder ball 35 at a joint between the circuit board 20 and the solder ball 35 and a point D at a joint between the chip 33 and the solder balls 35 are simulated. An acceleration curve (shown in FIG. 5) is used for simulating the impact applied on the circuit board 20. According to the simulation results, when the ratio P/H is greater than or equal to 0.5% and is less than or equal to 2.5%, the tensile stress applied on the points A and D can be effectively counteracted by the compressive stress applied on the solder balls 35 by the stress adjusting members 80. Thus, the solder balls 35 are protected from damage.

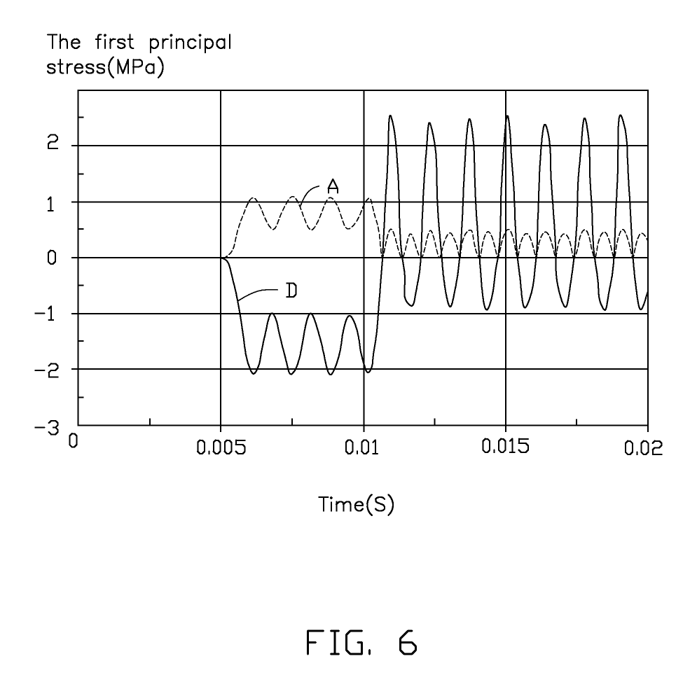

FIG. 6 shows the first principal stress distribution of the points A and D of a conventional heat dissipating system under the impact described in FIG. 5. The conventional heat dissipating system is similar to the embodiment of the heat dissipating system, but does not include the stress adjusting members 80 and the second clamping member 70. In FIG. 6, the broken line shows the first principal stress distribution of the point A at a joint between the chip and a solder ball. The real line shows the first principal stress distribution of the point D at a joint between the solder ball and the circuit board. When the first principal stress value is positive, the solder balls suffer tensile stress. When the first principal stress value is negative, the solder balls suffer compressive stress. Generally, the solder balls are not damaged under greater compressive stress, but may be easily damaged under greater tensile stress. As shown in FIG. 6, the first principal stress values on the point A are all positive, and most of the stress values on the point D are positive and exceed 2 MPa. So, points A and D suffer great tensile stress, and are easily damaged.

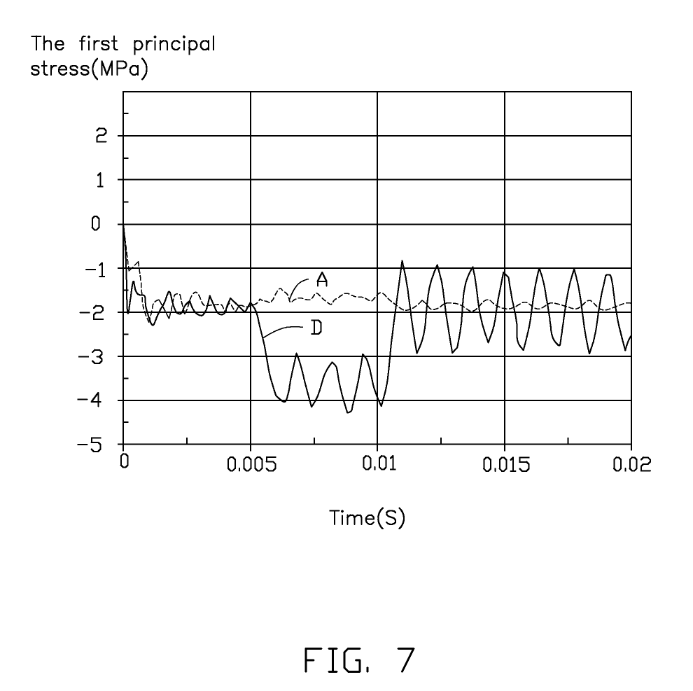

FIG. 7 shows the first principal stress distribution of the points A and D of the heat dissipating system of one embodiment of the heat dissipating system when the ratio P/H value is 1%. The first principal stress values of the points A and D of the solder balls 35 are all negative. That is, when the heat dissipating system suffers impact, the points A and D of the solder balls 35 suffer only compressive stress, of a value small enough to be afforded and may not damage the solder balls. In actual use, the P/H value may be adjusted according to the expected external impact, to adjust the tensile stress applied on the solder balls 35, which are thereby protected from damage.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A heat dissipating system comprising:
a circuit board comprising a top surface and a bottom surface opposite to the top surface;
a chip module, the chip module comprising a base portion located on the top surface of the circuit board via solder balls and a chip disposed on the base portion;
a first clamping member abutting the chip;
a second clamping member abutting the bottom surface of the circuit board; and
a plurality of stress adjusting members extending through the second clamping member and engaging with the first clamping member.

2. The heat dissipating system of claim 1, wherein a supporting member is located on the base portion and defines an opening receives the chip.

3. The heat dissipating system of claim 2, wherein a height of the chip is substantially equal to the height of the supporting member.

4. The heat dissipating system of claim 1, wherein a plurality of fixing holes is defined in the first clamping member; a plurality of mounting holes is defined in the second clamping member; a plurality of through holes is defined in the circuit board; and the plurality of stress adjusting members extend through the plurality of the mounting holes and the plurality of through holes and is inserted into the plurality of fixing holes.

5. The heat dissipating system of claim 4, wherein a ratio of a length of the plurality of stress adjusting members received in the plurality of fixing holes of the first clamping member to a distance between the top surface of the circuit board and a bottom surface of the base portion, that faces the circuit board is greater than or equal to 0.5% and is less than or equal to 2.5%.

6. The heat dissipating system of claim 4, wherein a ratio of a length of the plurality of stress adjusting members received in the plurality of fixing holes of the first clamping member to a height of the solder balls is greater than or equal to 0.5% and less than or equal to 2.5%.

7. The heat dissipating system of claim 1, wherein a chassis comprises a bottom wall, the circuit board is secured to and parallel to the bottom wall, and the second clamping member is located between the circuit board and the bottom wall.

8. The heat dissipating system of claim 1, wherein the first clamping member is a heat sink.

9. A heat dissipating system comprising:
a circuit board comprising a first side and a second side opposite to the first side;
a chip module secured to the first side of the circuit board via solder balls;
a first clamping member abutting the chip module;
a second clamping member abutting the second side of the circuit board; and
a plurality of stress adjusting members extending through the second clamping member and engaging with the first clamping member, to adjust compressive stress applied on the chip module.

10. The heat dissipating system of claim 9, wherein the chip module comprises a base portion and a chip located on the base portion; and a supporting member is located on the base portion and defines an opening receives the chip.

11. The heat dissipating system of claim 10, wherein a height of the chip is substantially equal to the height of the supporting member.

12. The heat dissipating system of claim 10, wherein a plurality of fixing holes is defined in the first clamping member; a plurality of mounting holes is defined in the second clamping member; a plurality of through holes is defined in the circuit board; and the plurality of stress adjusting members extend through the plurality of the mounting holes and the plurality of through holes and is inserted into the plurality of fixing holes.

13. The heat dissipating system of claim 12, wherein a ratio of a length of the plurality of stress adjusting members received in the plurality of fixing holes of the first clamping member to a distance between the first side of the circuit board and a side of the base portion, that is adjacent the circuit board, is greater than or equal to 0.5% and is less than or equal to 2.5%.

14. The heat dissipating system of claim 12, wherein a ratio of a length of the plurality of stress adjusting members received in the plurality of fixing holes of the first clamping member to a height of the solder balls is greater than or equal to 0.5% and less than or equal to 2.5%.

15. The heat dissipating system of claim 9, wherein a chassis comprises a bottom wall, the circuit board is secured to and parallel to the bottom wall, and the second clamping member is located between the circuit board and the bottom wall.

16. The heat dissipating system of claim 9, wherein the first clamping member is a heat sink.

17. A heat dissipating system comprising:
a chassis comprising a bottom wall;
a circuit board secured to and parallel to the bottom wall, the circuit board comprising a first side and a second side opposite to the first side;
a chip module secured to the first side of the circuit board via solder balls;
a heat sink abutting the chip module;
a second clamping member located between the second side of the circuit board and the bottom wall; and
a plurality of stress adjusting members fixed in the second clamping member and the heat sink.

18. The heat dissipating system of claim 17, wherein the chip module comprises a base portion and a chip located on the base portion; a supporting member is located on the base portion and defines an opening receives the chip; and a height of the chip is substantially equal to the height of the supporting member.

19. The heat dissipating system of claim 18, wherein a plurality of fixing holes is defined in the heat sink; a plurality of mounting holes is defined in the second clamping member; a plurality of through holes is defined in the circuit board; and the plurality of stress adjusting members extend through the plurality of the mounting holes and the plurality of through holes and is inserted into the plurality of fixing holes.

20. The heat dissipating system of claim 19, wherein a ratio of a length of the plurality of stress adjusting members received in the plurality of fixing holes of the heat sink to a distance between the circuit board and the base portion is greater than or equal to 0.5% and is less than or equal to 2.5%.
